(19) United States
(12) Patent Application Publication
(10) Pub. No.: US 2018/0277572 A1
(43) Pub. Date: Sep. 27, 2018

(54) FLEXIBLE DISPLAY PANELS AND THE MANUFACTURING METHODS THEREOF

(71) Applicant: Wuhan China Star Optoelectronics Technology Co., Ltd., Wuhan, Hubei (CN)

(72) Inventor: Yun YU, Shenzhen, Guangdong (CN)

(73) Assignee: Wuhan China Star Optoelectronics Technology Co., Ltd., Wuhan, Hubei (CN)

(21) Appl. No.: 15/540,549

(22) PCT Filed: Jun. 13, 2017
(86) PCT No.: PCT/CN2017/088022

§ 371 Date: Jun. 28, 2017

(30) Foreign Application Priority Data
Mar. 27, 2017 (CN) 201710188355.1

(51) Int. Cl. H01L 27/12; H01L 23/00; H01L 25/18; H01L 25/00

(52) U.S. Cl. CPC H01L 27/1218; H01L 24/32; H01L 24/05; H01L 24/83; H01L 27/1266; H01L 24/27; H01L 2224/8385; H01L 25/50; H01L 2224/2929; H01L 2224/27003; H01L 2224/32145; H01L 2224/04026; H01L 25/18

(57) ABSTRACT

The present disclosure relates to a flexible display panel and the manufacturing method thereof. The flexible display panel includes a display area, a non-display area in a rim of the display area, and a chip bonding area arranged on the non-display area. The chip bonding area includes a supporting substrate, an adhesive layer, a flexible substrate, an inorganic insulation layer, an anisotropic conductive film (ACF) and a chip. The supporting substrate includes a main board and a protrusion for enhancing the bonding reliability. With such structure of the supporting substrate, the supporting substrate may greatly enhance the reliability of the bonding process with respect to the chip.

### BACKGROUND OF THE INVENTION

### 1. Field of the Invention

The present disclosure relates to display technology, and more particularly to a flexible display panel and the manufacturing method thereof.

### 2. Discussion of the Related Art

With the development of display technology, flexible display devices have been widely adopted. Flexible substrates of the flexible display device are usually made by organic materials having high temperature resistant, such as Polyimide (PI).

Currently, a chip may be bonded on the flexible display device by two methods below.

With respect to the first method, the chip is directly bonded on the flexible display panel, which is called as chip on glass (COG).

With respect to the second method, the chip is connected to the flexible display panel via a flexible circuit board (FPC), which is called as chip on film (COF).

Compared to conventional COF bonding method, the COG method bonding method is better for the following reasons:

(1) The chip is directly bonded on the panel, and the additional circuit board may be excluded. Thus, the cost is low.

(2) The pitch between the wirings of the chip may be very small, which contributes to the high-resolution pad area. At the same time, the wirings on the flexible circuit board is still huge.

(3) A length of the wirings on the flexible circuit board is great, which increases the dimension of the bonding area. The length of the wirings of the chip is smaller, which conserves the space and narrows down the border.

However, when the COG method is adopted to bond the chip on the flexible display substrate, the circuit is fragile and the bonding performance may not be good enough for the reason the substrate is flexible.

### SUMMARY

The present disclosure relates to a flexible display panel and the manufacturing method thereof to solve the above-mentioned problem.

In one aspect, a flexible display panel includes: a display area, a non-display area in a rim of the display area, and a chip bonding area arranged on the non-display area; the chip bonding area includes a supporting substrate, an adhesive layer, a flexible substrate, an inorganic insulation layer, an anisotropic conductive film (ACF) and a chip stacked in sequence, a plurality of bonding pads being arranged on a top surface of the inorganic insulation layer, and a location of the chip corresponding to the location of the bonding pad; the supporting substrate includes a main board and a protrusion arranged on a top surface of the main board, and the location of the protrusion corresponding to the bonding pad and the chip; an area between the flexible substrate and the main board without configured with the protrusion being formed as a thick adhesive layer, and an area configured with the protrusion between the flexible substrate and the main board is formed as a thin adhesive layer; wherein the protrusion is configured to support when the chip and the bonding pad are bonded, and the thin adhesive layer is configured to reduce a buffering distance during a bonding process so as to enhance a bonding reliability; wherein the supporting substrate is made by PET, and the flexible substrate is made by PI.

In another aspect, a flexible display panel includes: a display area, a non-display area in a rim of the display area, and a chip bonding area arranged on the non-display area; the chip bonding area includes a supporting substrate, an adhesive layer, a flexible substrate, an inorganic insulation layer, an anisotropic conductive film (ACF) and a chip stacked in sequence, a plurality of bonding pads being arranged on a top surface of the inorganic insulation layer, and a location of the chip corresponding to the location of the bonding pad; the supporting substrate includes a main board and a protrusion arranged on a top surface of the main board, and the location of the protrusion corresponding to the bonding pad and the chip; an area between the flexible substrate and the main board without configured with the protrusion being formed as a thick adhesive layer, and an area configured with the protrusion between the flexible substrate and the main board is formed as a thin adhesive layer;

wherein the protrusion is configured to support when the chip and the bonding pad are bonded, and the thin adhesive layer is configured to reduce a buffering distance during a bonding process so as to enhance a bonding reliability.

Wherein the supporting substrate is made by PET, and the flexible substrate is made by PI.

Wherein a thickness of the supporting substrate is in a range from 25 microns to 50 microns.

Wherein the flexible substrate is made by PI.

Wherein the thickness of the flexible substrate is 20 microns.

Wherein the inorganic insulation layer includes a buffer (BF) layer, a gate insulation (GI) layer, and an interlayer insulation layer (ILD) stacked in sequence, and the bonding pad is arranged on a top surface of the ILD layer.

Wherein the protrusion is rectangular-shaped.

Wherein the ACF includes resin and a plurality of conductive particles arranged within the resin.

Wherein a plurality of bonding pads are configured, and the chip includes a plurality of golden fingers, and each of the golden fingers are arranged in the location corresponding to one bonding pad.

In another aspect, a manufacturing method of flexible display panels includes: forming a flexible substrate on a carrier substrate, and forming a component layer of a display area and forming the component layer of an non-display area; forming a bonding pad on the component layer of the non-display area; adhering the ACF to the bonding pad; peeling off the carrier substrate; bonding the supporting substrate configured with the protrusion with the flexible substrate via the adhesive layer, wherein a location of the protrusion corresponds to the location of the bonding pad; arranging the chip on the ACF, aligning the bonding pad and the protrusion, and performing a bonding process.

In view of the above, the structure of the supporting substrate is enhanced such that the great support is configured when the supporting substrate is bonded. At the same time, the thin adhesive layer may reduce a buffering distance during the bonding process so as to enhance the bonding reliability.

### BRIEF DESCRIPTION OF THE DRAWINGS

FIG. 1 is a top view of the flexible display panel in accordance with one embodiment of the present disclosure.

FIG. 2 is a cross sectional view of the flexible display panel in FIG. 1 along the “a-a” line.

FIG. 3 is a flowchart illustrating the manufacturing method of the flexible display panel in accordance with one embodiment of the present disclosure.

### DETAILED DESCRIPTION OF THE EMBODIMENTS

Embodiments of the invention will now be described more fully hereinafter with reference to the accompanying drawings, in which embodiments of the invention are shown.

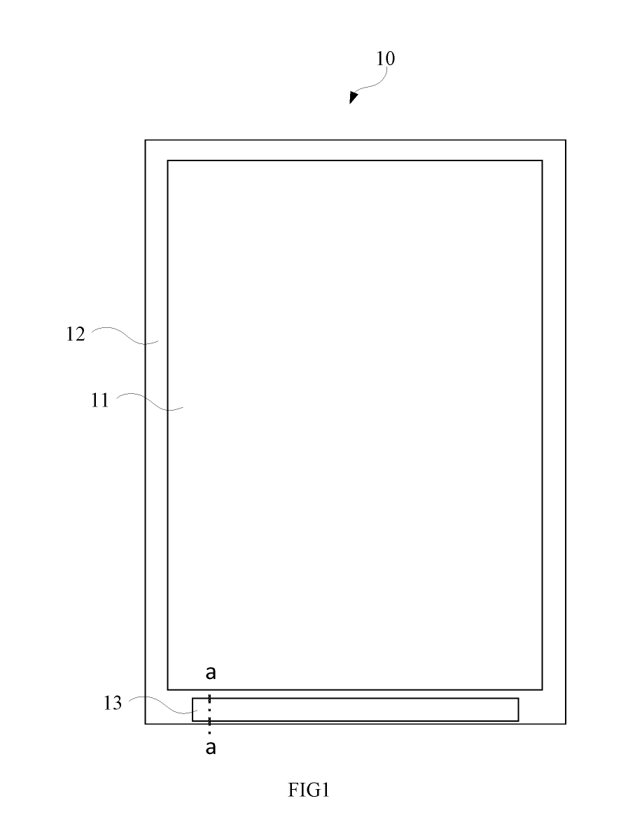

FIG. 1 is a top view of the flexible display panel in accordance with one embodiment of the present disclosure.

As shown in FIG. 1, the flexible display panel 10 includes a display area 11, a non-display area 12 in a rim of the display area 11, and a chip bonding area 13 arranged on the non-display area 12. A portion of the structure of the display area 11 may be referenced to conventional ones, and thus are omitted hereinafter.

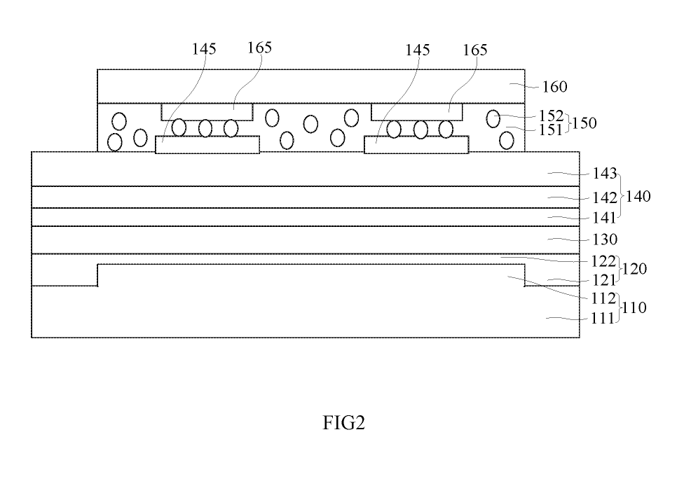

FIG. 2 is a cross sectional view of the flexible display panel in FIG. 1 along the “a-a” line.

As shown in FIG. 2, the chip bonding area 13 includes a supporting substrate 110, an adhesive layer 120, a flexible substrate 130, an inorganic insulation layer 140, an anisotropic conductive film (ACF) 150 and a chip 160 stacked in sequence.

A plurality of bonding pads 145 are arranged on a top surface of the inorganic insulation layer 140, and a plurality of golden fingers 165 are arranged on a down surface of the chip 160. Each of the golden fingers 165 are arranged in the location corresponding to one bonding pad 145. The ACF 150 includes resin 151 and a plurality of conductive particles 152 arranged within the resin 151.

In one embodiment, the supporting substrate 110 includes a main board 111 and a protrusion 112 arranged on a top surface of the main board 111. The protrusion 112 is rectangular-shaped, and the location of the protrusion 112 corresponds to the bonding pad 145 and the chip 160.

Due to the supporting substrate 110, an area between the flexible substrate 130 and the main board 111 without configured with the protrusion 112 is formed as a thick adhesive layer 121, and the area configured with the protrusion 112 between the flexible substrate 130 and the main board 111 is formed as a thin adhesive layer 122.

Due to the structure of the supporting substrate 110, the protrusion 112 provides great support when the golden fingers 165 on the chip 160 are bonded with the bonding pads 145 on the inorganic insulation layer 140. At the same time, the thin adhesive layer 122 may reduce a buffering distance during the bonding process so as to enhance the bonding reliability.

Conventionally, the supporting substrate 110 may be flat, and the thicknesses of the adhesive layer 120 are the same with respect to the bonding area and the non-bonding area. When being bonded, the applied stress of the conductive particles 152 within the ACF 150 is not huge enough due to the deformation. As such, the electrical contact between the golden fingers 165 of the chip 160 and the bonding pad 145 are not good enough.

In the embodiment, the supporting substrate 110 may be made by PET, wherein the hardness of the PET is greater than the flexible substrate, and the thickness may be in a range from 25 microns to 50 microns. That is, the thickness of the supporting substrate 110 may be 25, 30, 35, 40, 45, or 50 microns. The flexible substrate 130 may be made by PI, and the thickness of the flexible substrate 130 is smaller than that of the supporting substrate 110, and the thickness of the flexible substrate 130 is about 20 microns.

In one embodiment, the inorganic insulation layer 140 includes a buffer (BF) layer 141, a gate insulation (GI) layer 142, and an interlayer insulation layer (ILD) 143 stacked in sequence. The bonding pad 145 is arranged on the top surface of the ILD layer 143.

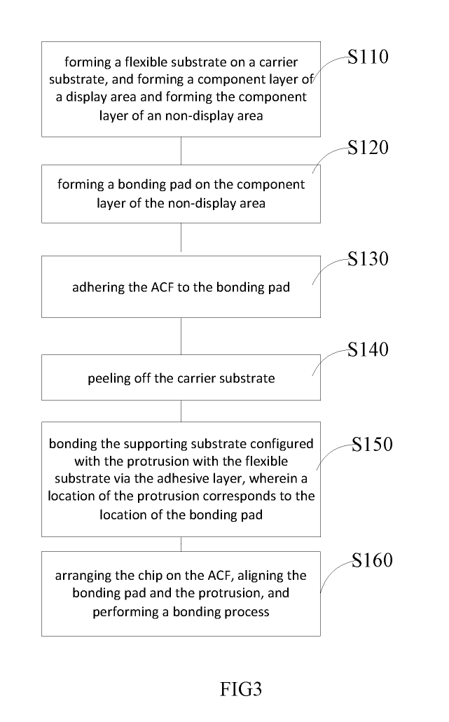

FIG. 3 is a flowchart illustrating the manufacturing method of the flexible display panel in accordance with one embodiment of the present disclosure.

As shown in FIG. 3, the method includes the following steps:

In step S110, forming a flexible substrate 130 on a carrier substrate, and forming a component layer of a display area and forming the component layer of an non-display area. In this step, as the thickness of the flexible substrate 130 is not suitable for more than ten manufacturing processes, and thus the glass substrate is adopted as a carrier substrate. The flexible substrate 130 may be formed by a coating method, and the thickness of the coating may be about 20 microns. The component layer of the display area and the non-display area may be referenced in the conventional solution, and thus are omitted hereinafter.

In step S120, forming a bonding pad 145 on the component layer of the non-display area. In this step, the component layer of the non-display area relates to the inorganic insulation layer 140, and a plurality of bonding pads 145 are formed on the top ILD layer 143 arranged on the inorganic insulation layer 140.

In step S130, adhering the ACF 150 to the bonding pad 145. In this step, the ACF 150 may be adopted to press the chip 160 in the manufacturing processes afterward.

In step S140, peeling off the carrier substrate.

In step S150, bonding the supporting substrate 110 configured with the protrusion 112 with the flexible substrate 130 via the adhesive layer 120. In this step, the adhesive layer 120 is transparent optical glue, and the location of the protrusion 112 corresponds to the location of the bonding pad 145.

In step S160, arranging the chip 160 on the ACF 150, aligning the bonding pad 145 and the protrusion 112, and performing a bonding process.

Due to the structure of the supporting substrate 110, the protrusion 112 provides great support when the golden fingers 165 on the chip 160 are bonded with the bonding pads 145 on the inorganic insulation layer 140. At the same time, the thin adhesive layer 122 may reduce a buffering distance during the bonding process so as to enhance the bonding reliability.

In view of the above, the structure of the supporting substrate is enhanced such that the great support is configured when the supporting substrate is bonded. At the same time, the thin adhesive layer 122 may reduce a buffering distance during the bonding process so as to enhance the bonding reliability.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A flexible display panel, comprising:
a display area, a non-display area in a rim of the display area, and a chip bonding area arranged on the non-display area;
the chip bonding area comprising a supporting substrate, an adhesive layer, a flexible substrate, an inorganic insulation layer, an anisotropic conductive film (ACF) and a chip stacked in sequence, a plurality of bonding pads being arranged on a top surface of the inorganic insulation layer, and a location of the chip corresponding to the location of the bonding pad;
the supporting substrate comprising a main board and a protrusion arranged on a top surface of the main board, and the location of the protrusion corresponding to the bonding pad and the chip;
an area between the flexible substrate and the main board without configured with the protrusion being formed as a thick adhesive layer, and an area configured with the protrusion between the flexible substrate and the main board is formed as a thin adhesive layer;
wherein the protrusion is configured to support when the chip and the bonding pad are bonded, and the thin adhesive layer is configured to reduce a buffering distance during a bonding process so as to enhance a bonding reliability;
wherein the supporting substrate is made by PET, and the flexible substrate is made by PI.

2. A flexible display panel, comprising:
a display area, a non-display area in a rim of the display area, and a chip bonding area arranged on the non-display area;
the chip bonding area comprising a supporting substrate, an adhesive layer, a flexible substrate, an inorganic insulation layer, an anisotropic conductive film (ACF) and a chip stacked in sequence, a plurality of bonding pads being arranged on a top surface of the inorganic insulation layer, and a location of the chip corresponding to the location of the bonding pad;
the supporting substrate comprising a main board and a protrusion arranged on a top surface of the main board, and the location of the protrusion corresponding to the bonding pad and the chip;
an area between the flexible substrate and the main board without configured with the protrusion being formed as a thick adhesive layer, and an area configured with the protrusion between the flexible substrate and the main board is formed as a thin adhesive layer;
wherein the protrusion is configured to support when the chip and the bonding pad are bonded, and the thin adhesive layer is configured to reduce a buffering distance during a bonding process so as to enhance a bonding reliability.

3. The flexible display panel as claimed in claim 2, wherein the supporting substrate is made by PET, and the flexible substrate is made by PI.

4. The flexible display panel as claimed in claim 2, wherein a thickness of the supporting substrate is in a range from 25 microns to 50 microns.

5. The flexible display panel as claimed in claim 2, wherein the flexible substrate is made by PI.

6. The flexible display panel as claimed in claim 2, wherein the thickness of the flexible substrate is 20 microns.

7. The flexible display panel as claimed in claim 2, wherein the inorganic insulation layer comprises a buffer (BF) layer, a gate insulation (GI) layer, and an interlayer insulation layer (ILD) stacked in sequence, and the bonding pad is arranged on a top surface of the ILD layer.

8. The flexible display panel as claimed in claim 2, wherein the protrusion is rectangular-shaped.

9. The flexible display panel as claimed in claim 2, wherein the ACF comprises resin and a plurality of conductive particles arranged within the resin.

10. The flexible display panel as claimed in claim 2, wherein a plurality of bonding pads are configured, and the chip comprises a plurality of golden fingers, and each of the golden fingers are arranged in the location corresponding to one bonding pad.

11. A manufacturing method of flexible display panels, comprising:
forming a flexible substrate on a carrier substrate, and forming a component layer of a display area and forming the component layer of an non-display area;
forming a bonding pad on the component layer of the non-display area;
adhering the ACF to the bonding pad;
peeling off the carrier substrate;
bonding the supporting substrate configured with the protrusion with the flexible substrate via the adhesive layer, wherein a location of the protrusion corresponds to the location of the bonding pad;
arranging the chip on the ACF, aligning the bonding pad and the protrusion, and performing a bonding process.
